(19) United States
(12) Patent Application Publication
(10) Pub. No.: US 2022/0007553 A1
(43) Pub. Date: Jan. 6, 2022

(54) CONDUCTIVE NONWOVEN FABRIC

(71) Applicant: SEKISUI CHEMICAL CO., LTD., Osaka (JP)

(72) Inventors: Takefumi KOYAMA, Aichi (JP); Katsunori MUTOU, Aichi (JP); Sachiko NAKAO, Aichi (JP); Kazuyuki YAHARA, Osaka (JP)

(73) Assignee: SEKISUI CHEMICAL CO., LTD., Osaka (JP)

(21) Appl. No.: 17/297,183

(22) PCT Filed: Nov. 28, 2019
(86) PCT No.: PCT/JP2019/046684

§ 371 Date: May 26, 2021

(30) Foreign Application Priority Data
Nov. 30, 2018 (JP) 2018-224969

(51) Int. Cl. H05K 9/00; B32B 5/02; B32B 15/14

(52) U.S. Cl. CPC H05K 9/009; B32B 5/022; H01Q 17/00; B32B 2307/202; B32B 2307/212; B32B 15/14

(57) ABSTRACT

A conductive nonwoven fabric comprising a metal layer on at least one surface thereof, the conductive nonwoven fabric having a sheet resistance of 200 to 600 Ω/□ and a density of 2.0×10⁴ to 8.×10⁵ g/m³. The conductive nonwoven fabric has higher radio wave absorption properties (high absorption and low reflectivity), even against high-frequency radio waves.

### TECHNICAL FIELD

The present invention relates to a conductive nonwoven fabric.

### BACKGROUND ART

In mobile communication devices, electronic devices, and household electrical appliances, components comprising a radio-wave-absorbing material have conventionally been used in order to prevent the leakage or intrusion of radio waves. Recently, particularly in electronic devices (information and communication devices) using radio waves, a radio wave absorber that absorbs unnecessary electromagnetic waves has been widely used from the standpoint of preventing the malfunction of other electronic devices and signal degradation, as well as preventing adverse effects on the human body. As the radio wave absorber, one obtained by dispersing magnetic metal powder in various rubber or resin materials is used. Patent Literature (PTL) 1, for example, reports a noise-absorbing fabric with a metal attached to its surface.

### CITATION LSIT

### Patent Literature

PTL 1: Japanese Patent No. 5722608

### SUMMARY OF INVENTION

### Technical Problem

As high-speed and large-capacity communication systems, such as 5G and IoT, are constructed, it is assumed that noise from electronic devices increases. However, the radio wave absorbers currently used as a countermeasure have difficulty in dealing with the high frequencies (e.g., 28 GHz, 39 GHz, and 79 GHz) used for SG or millimeter wave radar.

Accordingly, the present invention aims to provide a material having higher radio wave absorption properties (high absorption and low reflectivity), even against high-frequency radio waves.

### Solution to Problem

In light of the above object, the present inventors conducted extensive research. As a result, they found that the above object can be attained by a conductive nonwoven fabric comprising a metal layer, wherein the sheet resistance is 200 to 600 Ω/□, and the density is 2.0×10⁴ to 8.0×10⁵ g/m³. Based on this finding, the present inventors conducted further research, and accomplished the present invention.

Specifically, the present invention includes the following embodiments.

Item 1. A conductive nonwoven fabric comprising a metal layer on at least. one surface thereof, the conductive nonwoven fabric having a sheet resistance of 200 to 600 Ω/□ and a density of 2.0×10⁴ to 8.0×10⁵ g/m³.

Item 2. The conductive nonwoven fabric according to Item 1, having an adhesion amount of a metal element and/or a metalloid element of 5 to 150 μg/cm².

Item 3. The conductive nonwoven fabric according to Claim 1 or 2, comprising a barrier layer containing at least one element selected from the group consisting of nickel, silicon, titanium, and aluminum on at least one surface of the metal layer.

Item 4. The conductive nonwoven fabric according to any one of Items 1 to 3, wherein the metal layer contains at least one element selected from the group consisting of nickel, molybdenum, chromium, titanium, and aluminum.

Item 5. The conductive nonwoven fabric according to any one of Items 1 to 4, wherein the slope of change in high brightness area percentage measured with an X-ray CT apparatus is −3000 or more and −10 or less.

Item 6. A radio wave absorber comprising the conductive nonwoven fabric according to any one of Items 1 to 5.

Item 7. The radio wave absorber according to Item 6, wherein the conductive nonwoven fabric further comprises an adhesive layer.

Item 8. The radio wave absorber according to Item 6 or 7, wherein the thickness d of the conductive nonwoven fabric satisfies formula (1): λ/16≤d, wherein λ is the wavelength of a target radio wave.

Item 9. The radio wave absorber according to Item 8, comprising the conductive nonwoven fabric and a reflective layer, wherein the reflective layer is placed on a surface opposite to the surface of the conductive nonwoven fabric having a sheet resistance of 200 to 600 Ω/□.

Item 10. A chassis comprising the radio wave absorber according to any one of Items 6 to 9.

Item 11. The chassis according to Item 10, wherein the conductive nonwoven fabric is placed on an inner surface of the chassis.

Item 12. The chassis according to Item 10, wherein the conductive nonwoven fabric is placed in an opening of the chassis.

Item 13. An electronic device comprising the radio wave absorber according to any one of Items 6 to 9 or the chassis according to any one of Items 10 to 12.

### Advantageous Effects of Invention

The present invention can provide a material (conductive nonwoven fabric) having higher radio wave absorption properties (high absorption, low reflectivity), even against high frequencies. The use of this conductive nonwoven fabric can provide various radio wave absorbers.

### BRIEF DESCRIPTION OF DRAWINGS

FIG. 1 illustrates a schematic cross-section illustrating an embodiment of the conductive nonwoven fabric of the present invention comprising a metal layer and a nonwoven fabric.

FIG. 2 illustrates a schematic cross-section illustrating an embodiment of the conductive nonwoven fabric of the present invention comprising a metal layer, barrier layers, and a nonwoven fabric.

FIG. 3 illustrates a schematic cross-section illustrating an embodiment in which the radio wave absorber of the present invention is placed on an opening of a chassis and the inner wall of the chassis.

FIG. 4 illustrates a schematic cross-section illustrating an embodiment in which the radio wave absorber of the present invention is used so that it covers the source of radio wave noise.

FIG. 5 illustrates a schematic cross-section illustrating an embodiment in which the radio wave absorber of the present invention is placed inside a resin chassis.

FIG. 6 illustrates a schematic cross-section illustrating an embodiment of the radio wave absorber of the present invention comprising a dielectric layer, an adhesive layer, and a reflective layer, in addition to the conductive nonwoven fabric of the present invention.

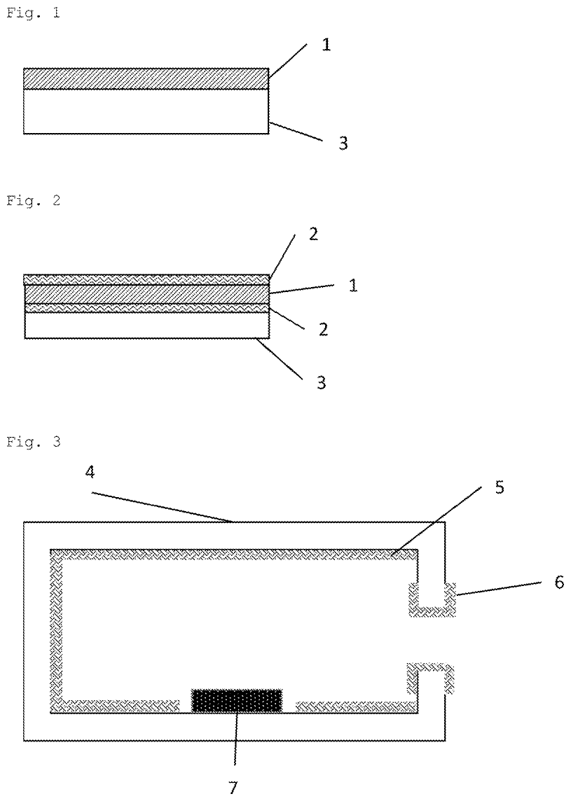

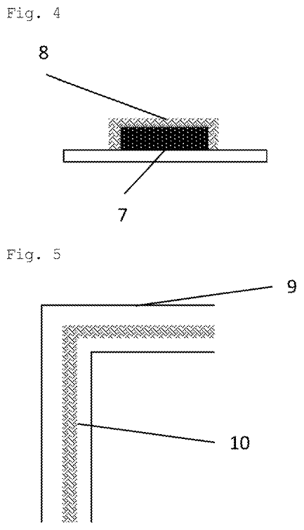

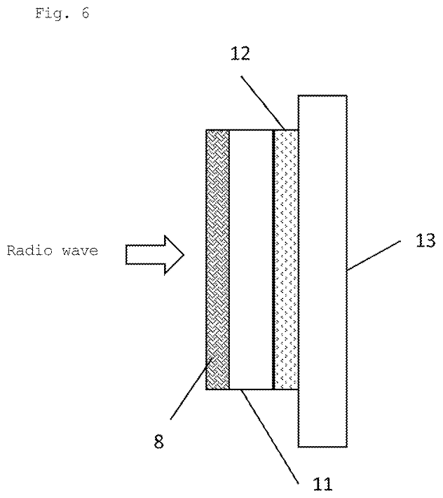

### DESCRIPTION OF EMBODIMENTS

In the present specification, the telcos “comprise,” “contain,” and “include” includes the concepts of comprising, containing, including, consisting essentially of, and consisting of.

In an embodiment, the present invention relates to a conductive nonwoven fabric comprising a metal layer on at least one surface of the conductive nonwoven fabric, wherein the conductive nonwoven fabric has a sheet resistance of 200 to 600 Ω/□ and a density of 2.0×10⁴ to 8.0×10⁵ g/m³ (in this specification, sometimes referred to as the “the conductive nonwoven fabric of the present invention”). This will be explained below. In the conductive nonwoven fabric of the present invention, the metal layer side relative to the nonwoven fabric is referred to as the “upper” side, whereas the nonwoven fabric side is referred to as the “lower” side.

### 1. Nonwoven Fabric

Any nonwoven fabric composed of fiber can be used. The nonwoven fabric may contain a component other than the fiber, a material, or the like, as long as the effect of the present invention is not impaired. In this case, the total amount of fiber in the nonwoven fabric is, for example, 80 mass % or more, preferably 90 mass % or more, more preferably 95 mass % or more, even more preferably 99 mass % or more, and typically less than 100 mass %.

The layer structure of the nonwoven fabric is not particularly limited. The nonwoven fabric may be composed of a single nonwoven fabric, or a combination of two or more nonwoven fabrics.

The material constituting the fiber is not particularly limited, as long as the material is fibrous or can be formed into a fibrous form. Examples of the fiber material include polyester-based resins, such as polyethylene terephthalate (PET), polybutylene terephthalate (PBT), polyethylene naphthalate, and modified polyester; polyolefin resins, such as polyethylene (PE) resin, polypropylene (PP) resin, polystyrene resin, and cyclic olefin-based resin; vinyl-based resins, such as polyvinyl chloride and polyvinylidene chloride; polyvinyl acetal resins, such as polyvinyl butyral (PVB); synthesis resins, such as polyether ether ketone (PEEK) resin, polysulfone (PSF) resin, polyether sulfone (PES) resin, polycarbonate (PC) resin, polyamide resin, polyimide resin, acrylic resin, and triacetyl cellulose (TAO) resin; natural resins; cellulose; glass; and the like. The fiber may be composed of a single fiber material, or a combination of two or more fiber materials.

The basis weight (g/m²) of the nonwoven fabric is, for example, 1 to 500 g/m², preferably 3 to 300 g/m², more preferably 5 to 150 g/m².

The thickness of the nonwoven fabric is, for example, 1 to 3000 μm, preferably 5 to 1500 μm, and more preferably 10 to 800 μm.

The lower limit of the density of the nonwoven fabric is preferably 2.0×10⁴ g/m³, more preferably 1.0×10⁵ g/m³, and even more preferably 1.5×10⁵ g/m³. The upper limit of the density of the nonwoven fabric is preferably 8.0×10⁵ g/m³, and more preferably 6.0×10⁵ g/m³.

When the density of the nonwoven fabric is within the above ranges, the density of the conductive nonwoven fabric of the present invention can be easily adjusted to the above range. This will consequently improve the radio wave absorption of the conductive nonwoven fabric.

The reason for this is not bound by any specific theory. However, it is considered that the use of a nonwoven fabric having a density within a specific range not only allows metal to adhere to the surface of the nonwoven fabric, but also allows metal to enter inside the nonwoven fabric, thus improving radio wave absorption properties (in particular, absorption).

### 2. Metal Layer

The metal layer is placed on the nonwoven fabric. In other words, the metal layer is placed on at least one surface of the two principal surfaces of the nonwoven fabric.

The metal layer is not particularly limited, as long as the layer contains a metal as a material. The metal layer may contain a component other than the metal, as long as the effect of the present invention is not significantly impaired. In this case, the amount of metal in the metal layer is, for example, 80 mass % or more, preferably 90 mass % or more, more preferably 95 mass % or more, even more preferably 99 mass % or more, and typically less than 100 mass %.

The metal constituting the metal layer is not particularly limited, as long as it can exhibit radio wave absorption properties. Examples of metal include nickel, molybdenum, chromium, titanium, aluminum, gold, silver, copper, zinc, tin, platinum, iron, indium, alloys containing these metals, and metal compounds of these metals or alloys containing these metals. It is preferred that the metal layer contains at least one metal element selected from the group consisting of nickel, molybdenum, chromium, titanium, and aluminum, from the standpoint of inhibiting the change of the radio wave absorption properties in the conductive nonwoven fabric over time (durability).

When the metal layer contains at least one metal element selected from the group consisting of nickel, molybdenum, chromium, titanium, and aluminum as mentioned above, the content thereof is, for example, 10 mass % or more, preferably 20 mass % or more, more preferably 40 mass % or more, even more preferably 60 mass % or more, and typically less than 100 mass %.

As the metal layer, a metal layer containing molybdenum is preferably used from the standpoint of ease of adjusting durability and sheet resistance. The lower limit of the content of molybdenum is not particularly limited; from the standpoint of increasing durability, it is preferably 5 wt %, more preferably 7 wt %, even more preferably 9 wt %, still more preferably 11 wt %, particularly preferably 13 wt %, very preferably 15 wt %, and most preferably 16 wt %. The upper limit of the content of the molybdenum is preferably 70 wt %, more preferably 30 wt %, even more preferably 25 wt %, and still more preferably 20 wt %, from the standpoint of ease of adjusting the value of surface resistance.

More preferably, the metal layer that contains molybdenum further contains nickel and chromium. A metal layer containing nickel and chromium in addition to molybdenum leads to a conductive nonwoven fabric with excellent durability. Examples of alloys containing nickel, chromium, and molybdenum include a variety of alloy grades such as Hastelloy B-2, B-3, C-4, C-2000, C-22, C-276, G-30, N, N, and X.

The metal layer containing molybdenum, nickel, and chromium preferably contains molybdenum in an amount of 5 wt % or more, nickel in an amount of 40 wt % or more, and chromium in an amount of 1 wt % or more. The metal layer containing molybdenum, nickel, and chromium in amounts within these ranges leads to a conductive nonwoven fabric with further improved durability. The metal layer more preferably contains molybdenum in an amount of 7 wt % or more, nickel in an amount of 45 wt % or more, and chromium in an amount of 3 wt % or more. The metal layer still more preferably contains molybdenum in an amount of 9 wt % or more, nickel in an amount of 47 wt % or more, and chromium in an amount of 5 wt % or more. The metal layer yet more preferably contains molybdenum in an amount of 11 wt % or more, nickel in an amount of 50 wt % or more, and chromium in an amount of 10 wt % or more. The metal layer particularly preferably contains molybdenum in an amount of 13 wt % or more, nickel in an amount of 53 wt % or more, and chromium in an amount of 12 wt % or more. The metal layer very preferably contains molybdenum in an amount of 15 wt % or more, nickel in an amount of 55 wt % or more, and chromium in an amount of 15 wt % or more. The metal layer most preferably contains molybdenum in an amount of 16 wt % or more, nickel in an amount of 57 wt % or more, and chromium in an amount of 16 wt % or more. Additionally, the nickel content in the metal layer is preferably 80 wt % or less, more preferably 70 wt % or less, and still more preferably 65 wt % or less. The upper limit of the chromium content is preferably 50 wt % or less, more preferably 40 wt % or less, and still more preferably 35 wt % or less.

The metal layer may further contain metals other than molybdenum, nickel, or chromium. Examples of such metals include iron, cobalt, tungsten, manganese, and titanium. The upper limit of the total content of metals other than molybdenum, nickel, and chromium in the metal layer containing molybdenum, nickel, and chromium is preferably 45 wt %, more preferably 40 wt %, still more preferably 35 wt %, yet more preferably 30 wt %, particularly preferably 25 wt %, and very preferably 23 wt %, from the standpoint of durability of the metal layer. The lower limit of the total content of metals other than molybdenum, nickel, and chromium is, for example, 1 wt % or more.

When the metal layer contains iron, the upper limit of the content of iron is preferably 25 wt %, more preferably 20 wt %, and still more preferably 15 wt %, with the lower limit being preferably 1 wt % from the standpoint of durability of the metal layer. When the metal layer contains cobalt and/or manganese, the upper limit of the content of each metal is independently preferably 5 wt %, more preferably 4 wt %, and still more preferably 3 wt %, with the lower limit being preferably 0.1 wt % from the standpoint of durability of the metal layer. When the metal layer contains tungsten, the upper limit of the content of tungsten is preferably 8 wt %, more preferably 6 wt %, and still more preferably 4 wt %, with the lower limit being preferably 1 wt % from the standpoint of durability of the metal layer.

The metal may contain silicon and/or carbon. The metal layer containing silicon and/or carbon contains silicon and/or carbon in an individual amount of preferably 1 wt % or less, and more preferably 0.5 wt % or less. The metal layer containing silicon and/or carbon contains silicon and/or carbon in an individual amount of preferably 0.01 wt % or more.

The adhesion amount of a metal element and/or a metalloid element derived from the metal layer is not particularly limited, as long as it can satisfy the sheet resistance as described below. The adhesion amount of a metal element and/or a metalloid element derived from the metal layer is, for example, 5 to 150 μg/cm², preferably 10 to 100 μg/cm, more preferably 20 to 50 μg/cm.

The adhesion amount of a metal element and/or a metalloid element derived from the metal layer can be determined by X-ray fluorescence analysis. More specifically, the analysis is performed using a scanning X-ray fluorescence analyzer (e.g., a ZSX Primus III+X-ray fluorescence spectrometer, produced by Rigaku Corporation, or similar equipment) at an acceleration voltage of 50 kV, acceleration current of 50 mA, and integration time of 60 seconds. The X-ray intensity of the Kα ray of a component that is to be measured is measured, and the intensity at the background position is also measured in addition to the peak position so that the precise intensity can be calculated. From the calibration curve prepared beforehand, the measured intensity value can be converted into an adhesion amount. The same sample is analyzed five times, and the average value is defined as the average adhesion amount.

The layer structure of the metal layer is not particularly limited. The metal layer may be composed of a single metal layer, or a combination of two or more metal layers.

### 3. Barrier Layer

The conductive nonwoven fabric of the present invention preferably comprises a barrier layer on at least one surface (preferably both surfaces) of the metal layer.

The barrier layer can be any layer that can protect the metal layer, and that can suppress degradation of the metal layer. However, the composition of the barrier layer is preferably different from that of the metal layer. The material for the barrier layer can be, for example, a metal, a metalloid, an alloy, a metal compound, and a metalloid compound. The barrier layer may contain components other than these materials, to the extent that the effect of the present invention is not significantly impaired. In this case, the content of the material described above in the barrier layer is, for example, 80 mass % or more, preferably 90 mass % or more, more preferably 95 mass % or more, and still more preferably 99 mass % or more; and typically less than 100 mass %.

Examples of metals preferably used for the barrier layer include nickel, titanium, aluminum, niobium, and cobalt. Examples of metalloids preferably used for the barrier layer include silicon, germanium, antimony, and bismuth.

Examples of the metal compound and the metalloid compound used in the barrier layer include SiO₂, SiOx (X represents an oxidation number, 0<X<2), Al₂O₃, MgAl₂O₄, CuO, CuN, TiO₂, TiN, AZO (aluminum doped zinc oxide), and the like.

The barrier layer preferably contains at least one element selected from the group consisting of nickel, silicon, titanium, and aluminum. Of these, silicon is preferred.

The adhesion amount of a metal element and/or a metalloid element derived from the barrier layer is not particularly limited, as long as it can satisfy the sheet resistance described below. The adhesion amount of a metal element and/or a metalloid element derived from the barrier layer is, for example 2 to 15 μg/cm², preferably 4 to 12 μg/cm² and more preferably 6 to 10 μg/cm².

The layer structure of the barrier layer is not particularly limited. The barrier layer may be composed of a single barrier layer, or a combination of two or more barrier layers.

### 4. Characteristics

The conductive nonwoven fabric of the present invention has a sheet resistance on at least one surface of 200 to 600 Ω/□ and a density of 2.0×10⁴ to 8.0×10 g/m³. Because it has such characteristics, higher radio wave transmission can be exhibited on the surface of the conductive nonwoven fabric, while radio waves can be absorbed inside the conductive nonwoven fabric. Thus, the conductive nonwoven fabric of the present invention can exhibit higher radio wave absorption properties (high absorption and low reflectivity) against high frequencies.

The sheet resistance is the surface resistance value on the surface of the metal layer side in the conductive nonwoven fabric of the present invention, which can be measured by four-terminal sensing with a surface resistance tester (a Loresta-EP or similar equipment, trade name, produced by Mitsubishi Chemical Analytech Co., Ltd.). Measurement is conducted using an ESP probe (an MCP-TP08P or similar equipment) by uniformly pressing all pins of a probe against a sample. The lower limit of the sheet resistance is 200 Ω/□, preferably 250 Ω/□, more preferably 300 Ω/□, and even more preferably 320 Ω/□. The upper limit of the sheet resistance is 600 Ω/□, preferably 500 Ω/□, and more preferably 450 Ω/□. A sheet resistance within the above range will further improve radio wave absorption properties (in particular, low reflectivity).

When the surface of the conductive nonwoven fabric on the metal layer side is protected and insulated by a resin sheet or the like, the sheet. resistance can be measured by an eddy current method using a non-contact resistance measurement instrument (an EC-80P or similar equipment, trade name, produced by Tapson Corporation).

The density is the density of the conductive nonwoven fabric of the present invention. The density can be calculated from the following formula (1), wherein the thickness of a sample obtained by measurement according to the method specified in JIS L 1913:2010 is defined as a thickness, and the mass per unit area is defined as a basis weight.

Density (g/m³)=basis weight (g/m²)/thickness (m) formula (1)

When a specimen with a required size cannot be taken from the sample, the value measured by applying a load of 0.5 kPa to the sample can be taken as a thickness. The density of the conductive nonwoven fabric in the present invention is 2.0×10⁴ to 8.0×10⁵ g/m³. The lower limit of the density of the conductive nonwoven fabric according to the present invention is preferably 1.0×10⁵ g/m³, more preferably 1.5×10⁵ g/m³, and even more preferably 2.0×10⁵ g/m³. The upper limit of the density of the conductive nonwoven fabric according to the present invention is preferably 6.0×10³ g/m³, and more preferably 4.0×10⁵ g/m³. A density of the conductive nonwoven fabric within the above range will further improve radio wave absorption properties (in particular, high absorption).

The conductive nonwoven fabric of the present invention can be obtained by adhering an element constituting the metal layer (if necessary, including an element constituting the barrier layer) to the nonwoven fabric. The adhesion amount of the element (the adhesion amount of the metal element and/or metalloid element) is preferably 5 to 150 μg/cm², in terms of radio wave absorption properties. The adhesion amount is more preferably 15 to 100 μg/cm², and even more preferably 30 to 60 μg/cm².

The conductive nonwoven fabric of the present invention preferably has a gradient in the amount of metal adhesion between its surface (the surface having a sheet resistance of 200 to 600 Ω/□) and the inside thereof. The gradient in the amount of metal adhesion will further improve radio wave absorption properties (in particular, high absorption). The reason for this is not bound by any particular theory; however, since the conductive nonwoven fabric has a gradient in the amount of metal adhesion, radio waves entering from the outside are trapped on the surface with high metal adhesion. At this time, the conductive nonwoven fabric having a specific value of sheet resistance can suppress the reflection of radio waves.

Incident radio waves are converted to electric current in the process of passing through the conductive nonwoven fabric of the present invention, and absorbed and attenuated. The inside of the conductive nonwoven fabric of the present invention has low metal adhesion as compared to its surface; i.e., it has high electrical resistance. This leads to multiple reflections in the conductive nonwoven fabric, which may more easily result in absorption and attenuation.

The gradient in the amount of metal adhesion can be adjusted by adjusting the density of the nonwoven fabric, the amount of metal adhesion, or the adhesion method (e.g., adjustment of a sputtering method described below).

The gradient in the amount of metal adhesion can be confirmed by photographing with an X-ray CT apparatus. Since the metal adhesion area has higher X-ray absorption than that of a fiber itself constituting the conductive nonwoven fiber, a photographed image can be obtained as a high brightness area.

The gradient in the amount of metal adhesion between the surface of the conductive nonwoven fabric (the surface having a sheet resistance of 200 to 600 Ω/□) and the inside thereof is such that the slope of change in metal distribution measured by an X-ray CT apparatus is preferably −10 or less, more preferably −15 or less, and even more preferably −18 or less. The slope of change in the high brightness area percentage is preferably −3000 or more, more preferably −2500 or more, even more preferably −2375 or more, still more preferably −1800 or more, and particularly preferably −1523 or more.

Due to the metal distribution as mentioned above, the gradient occurring from the surface of the conductive nonwoven fabric to the inside thereof is formed deep inside the conductive nonwoven fabric. This will further improve radio wave absorption properties (in particular, high absorption).

The slope of change in metal distribution means the slope of the graph showing the high brightness area percentage and the thickness, which is calculated by plotting the thickness position on the X-axis (mm) and the high brightness area percentage ((the number of high brightness areas/the number of total brightness areas)×100 (5)) on the Y-axis by the analysis with an X-ray CT apparatus described below.

The slope is calculated by analyzing a cross-sectional image obtained by the X-ray CT apparatus. The specific method is as follows. A conductive nonwoven fabric is cut into a size of about 3 mm×3 mm×3 mm to prepare a measurement sample. The measurement sample is measured with an X-ray microscope (a nano3DX or similar equipment, produced by Rigaku Corporation), thus obtaining a three-dimensional image. Binning 2 and the exposure time are set within the recommended time of the measurement device, and photographing is performed under the condition of the number of photographs being 1200. As an X-ray source, a source that can detect a metal in the metal layer, such as Mo and W, can be used. A lens with a number of pixels that is capable of confirming the diameter of a fiber constituting the conductive nonwoven fabric can be used. If the thickness of the conductive nonwoven fabric exceeds the field of view of the lens, multiple images are photographed, synthesized with image analysis software, and then used in analysis. The obtained three-dimensional image was analyzed with Avizo 9.7 (produced by Thermo Fisher Scientific) image analysis software and Image J Fiji image processing software (Dec. 30, 2017 version; open-source software; Schindelin, J., Arganda-Carreras, I., and Frise, E. et al. (2012), “Fiji: an open-source platform for biological-image analysis,” Nature Methods 9(7): 676-682).

The analysis can be performed, for example, as follows. Avizo 9.7 is used for the following Items (1) to (4), and Image J Fiji is used for the following Item (5).

(1) Images measured with an X-ray CT are taken as images having a 256-level (8-bit) brightness value, and reconstructed to obtain a three-dimensional image.
(2) The thickness direction is defined as the z-axis, and slice images in the x-y plane are formed in the order from the surface of the conductive nonwoven fabric having a sheet resistance of 200 to 600 Ω/□. Additionally, the images are cut so that each of the bottom surfaces of the x-y plane is quadrangle.
(3) Binarization is performed by the auto threshold function to select a conductive nonwoven fabric portion. Subsequently, noise is removed by opening to separate portions where the conductive nonwoven fabric is present, and portions where only air is present.
(4) By masking, only the portions where the conductive nonwoven fabric is present are extracted, and the brightness values of the other portions are adjusted to 0.
(5) Using image processing software, the count number of pixels having a brightness value of 1 or more (the number of total brightness areas) and the count number of pixels having a brightness value equal to or greater than the threshold value (the number of high brightness areas) are obtained for each slice image. The average of the maximum values of the brightness value in the range from the lower surface of the conductive nonwoven fabric to 5% of the thickness of the conductive nonwoven fabric is defined as the threshold value. The region with a brightness value of 0 is regarded as an air layer, and is not used in subsequent analysis.
(6) By plotting the thickness position and the high brightness area percentage ((the number of high brightness areas/the number of total brightness areas) x 100 (%)) on the X-axis (mm) and the Y-axis, respectively, a graph of the high brightness area percentage and the thickness is formed.

The slope of change in metal distribution (the slope of the graph of the high brightness area percentage and the thickness) can be calculated by determining the slope between two points: the point of the maximum value of the high brightness area percentage and the point indicating 10% of the maximum value of the high brightness area percentage in the thickness position greater than that of the point of the maximum value.

If there are multiple points of the maximum value of the high brightness area percentage, the value at the point closest to the surface of the conductive nonwoven fabric facing the metal layer is used.

If there is no point indicating 10% of the maximum value of the high brightness area percentage, the point of the minimum value of the high brightness area percentage in the thickness region where the conductive nonwoven fabric is present is used. If there are multiple points of the minimum value of the high brightness area percentage, the value at the point where the thickness position is greater than that of the point of the maximum value, and where the thickness position is the smallest is used.

The thickness region where the conductive nonwoven fabric is present means a region between the thickness position at the first point that indicates 20% of the maximum value of the number of total brightness area, and the thickness position at the last point that indicates 20% of the maximum value of the number of total brightness area.

In the graph of the high brightness area percentage and the thickness, the conductive nonwoven fabric preferably has a point indicating 50% or less of the maximum value of the high brightness area percentage in the thickness position greater than that of the point of the maximum value of the high brightness area percentage.

Since the conductive nonwoven fabric has a point indicating 50% or less of the maximum value of the high brightness area percentage, the inside of the conductive nonwoven fabric has a sufficiently large resistance value. This leads to multiple reflections in the conductive nonwoven fabric, which may more easily result in absorption and attenuation.

The conductive nonwoven fabric more preferably has a point indicating 30% or less of the maximum value of the high brightness area percentage, even more preferably a point indicating 20% or less of the maximum value of the high brightness area percentage, and still more preferably a point indicating 10%. or less of the maximum value of the high brightness area percentage.

In the graph of the high brightness area percentage and the thickness, the range of metal adhesion from the surface of the conductive nonwoven fabric is preferably from the surface of the conductive nonwoven fabric facing the metal layer to a thickness of 5 μm or more from its surface. This forms the gradient of metal adhesion deep inside the conductive nonwoven fabric. Accordingly, further improved radio wave absorption properties (in particular, high absorption) are attained. Metal distribution is preferably present at 10 μm or more, even more preferably 15 μm or more, and still more preferably 20 μm or more, from the surface of the conductive nonwoven fabric. The upper limit of the range of metal distribution present is not particularly limited; however, it is, for example, equal to or below the thickness of the conductive nonwoven fabric, 90% or less of the thickness of the conductive nonwoven fabric, 80% or less of the thickness of the conductive nonwoven fabric, 70% or less of the thickness of the conductive nonwoven fabric, or 60% or less of the thickness of the conductive nonwoven fabric.

In the graph of the high brightness area percentage and the thickness, the range of metal adhesion from the surface of the conductive nonwoven fabric means a region between the thickness position where the surface of the conductive nonwoven fabric has the metal layer to the thickness position at a point indicting 10% of the maximum value of the high brightness area percentage in the thickness position that is greater than that of the point of the maximum value of the high brightness area percentage. If the point indicating 10% of the maximum value of the high brightness area percentage is not present, a region from the thickness position where the surface of the conductive nonwoven fabric has the metal layer to the thickness position at a point indicting the minimum value of the high brightness area percentage in the thickness region where the conductive nonwoven fabric is present is used.

### 5. Production Method

The conductive nonwoven fabric of the present invention can be obtained by a method comprising the step of adhering a metal to the surface of the nonwoven fabric. If the conductive nonwoven fabric comprises another layer (e.g., a barrier layer) in addition to the metal layer, it can be obtained by a method comprising the step of adhering a constituent element of another layer to the surface of the nonwoven fabric, the surface of the metal layer, or the like.

Adhesion can be performed by any method. It is, for example, performed by sputtering, vacuum deposition, ion plating, chemical vapor deposition, or pulsed laser deposition. Of these, in terms of film thickness controllability and radio wave absorption properties, sputtering is preferable.

Sputtering can be of any type; examples include DC magnetron sputtering, high-frequency magnetron sputtering, and ion beam sputtering. The sputtering device may be a batch system, or a roll-to-roll system.

When the adhesion is performed by sputtering, the gradient in the amount of metal adhesion between the surface and the inside of the surface can be adjusted by gas pressure at the time of sputtering. By lowering the gas pressure at the time of sputtering, the metal can be adhered deeper inside the nonwoven fabric, and can be distributed with a gentle gradient.

### 6. Application

The conductive nonwoven fabric of the present invention can be preferably used as a radio wave absorber because it has high radio wave absorption properties (high absorption and low reflectivity), even against high-frequency radio waves. In this regard, the present invention relates to, in one embodiment, a radio wave absorber comprising the conductive nonwoven fabric of the present invention (in this specification, sometimes referred to as “the radio wave absorber of the present invention”).

It is preferred for the radio wave absorber of the present invention that the surface of the conductive nonwoven fabric having a sheet resistance of 200 to 600 Ω/□ is placed against the incident surface of the radio wave.

Due to its ability to absorb unnecessary radio waves, the radio wave absorber according to the present invention in one embodiment can be suitably used as an optical transceiver or a member for handling radio waves in next-generation mobile communications systems (5G). The radio wave absorber according to the present invention can also be used in order to reduce radio wave interference and noise in an intelligent transport system (ITS) that communicates between automobiles, roads, and people; and in millimeter-wave radar for use in automotive collision avoidance systems. The frequency of the radio wave targeted by the radio wave absorber in the present invention is, for example, 20 GHz or more and 150 GHz or less, preferably 25 GHz or more and 85 GHz or less.

In one embodiment, the radio wave absorber of the present invention comprises the conductive nonwoven fabric of the present invention and an adhesive layer. The adhesive layer allows the radio wave absorber of the present invention to easily adhere to a molded product or a product such as a chassis. For example, the adhesive layer may be placed on the metal layer side of the conductive nonwoven fabric, or the adhesive layer may be placed on the surface not facing the metal layer. As the adhesive layer, known adhesives, pressure-sensitive adhesives (adhesives), and the like can be used.

In one embodiment, the radio wave absorber of the present invention may be used by covering the surroundings of a target object for radio wave absorption. Accordingly, the radio wave absorber is suitably molded according to the shape of the object. The molded product is referred to as “the radio wave absorption molded product” in this specification.

Any target object for radio wave absorption can be used. Examples of the target object for radio wave absorption include electronic components such as LSIs, the surface or back surface of circuits such as glass epoxy substrates and FPCs, connection cables and connector parts between components, chassis for incorporating electronic components or devices, the backside or front side of holding bodies, and cables such as power lines and transmission lines.

The method of covering the surroundings is not particularly limited, and includes wrapping and adhering.

In one embodiment, a chassis with excellent radio wave absorption can be obtained by applying the radio wave absorber of the present invention to the chassis via an adhesive or the like. The chassis having the conductive nonwoven fabric of the present invention is also one of the present inventions.

In one embodiment, a chassis with excellent radio wave absorption can be obtained by adhering the radio wave absorber of the present invention to the inner surface (more preferably, inner wall) of the chassis incorporating an electronic device or the like via an adhesive.

The radio wave absorber of the present invention is placed away from the source of radio wave noise, and is used so that the radio wave absorber covers the surroundings of a target object for radio wave absorption. By this, the radio wave absorber of the present invention can efficiently exhibit the properties of absorbing unnecessary radio wave noise. Further, the radio wave absorber placed away from the source of radio wave noise is less likely to interfere with dissipation of heat generated by an LSI or the like. The radio wave absorber of the present invention is preferably present at least λ/2π away from the source of radio wave noise, in terms of radio wave absorption. Note that λ indicates the wavelength of a target radio wave. If radio wave noise occurs inside the chassis, the chassis itself can become a source of radio wave noise due to cavity resonance phenomenon. By placing the radio wave absorber of the present invention on the inner wall of the chassis, cavity resonance phenomenon can be suppressed, and noise generated from the chassis can also be suppressed.

A chassis including the conductive nonwoven fabric of the present invention in the inner surface of the chassis, and an electronic device comprising the chassis are also one of the present inventions.

In one embodiment, when the chassis incorporating an electronic device or the like has an opening, by adhering the wave absorber of the present invention to the opening, a chassis with excellent radio wave absorption can be obtained. When the chassis incorporating an electronic device or the like has an opening, radio wave noise generated from the electronic device in the chassis may leak from the opening; or the opening may act as an antenna, and re-radiate radio wave noise. In such a case, by providing the radio wave absorber of the present invention in the opening of the chassis, noise emitted from the chassis can be reduced.

A chassis comprising the conductive nonwoven fabric of the present invention in the opening of the chassis, and an electronic device comprising the chassis are also one of the present inventions.

In one embodiment, the radio wave absorption molded product of the present invention further comprises a nonconductive material. The nonconductive material can enhance the shape retainability of the radio wave absorption molded product.

By adhering the radio wave absorber of the present invention to a component composed of various nonconductive materials via an adhesive or the like, a radio wave absorption molded product having excellent radio wave absorption can be obtained. In particular, the radio wave absorber is preferably used for providing radio wave absorption by adhering to the surface of a chassis for incorporating an electronic device. A radio wave absorption molded product in which the radio wave absorber of the present invention is adhered to the surface of a component composed of a nonconductive material is also one of the present inventions. An electronic device that is incorporated in a chassis in which the radio wave absorber of the present invention is adhered to the surface of a component composed of a nonconductive material is also one of the present inventions.

A radio wave absorption molded product having excellent wave absorption can be obtained not only by adhering the radio wave absorber of the present invention to the surface of a component composed of a nonconductive material, but also by maintaining a component composed of a nonconductive material inside the radio wave absorber of the present invention. A radio wave absorption molded product, wherein the radio wave absorber of the present invention is held inside the component composed of a nonconductive material, is also one of the present inventions. An electronic device that is incorporated in a chassis in which the radio wave absorber of the present invention is held inside a component composed of a nonconductive material is also one of the present inventions.

In one embodiment, the radio wave absorber of the present invention further comprises a reflective layer. When the radio wave absorber has a reflective layer, the conductive nonwoven fabric of the present invention comprises a metal layer on only one side of the nonwoven fabric, and the reflective layer is placed on the side not facing the metal layer. The above configuration ensures more excellent radio wave absorption properties.

The reason therefor is not bound by any particular theory; however, the incident radio wave is absorbed and attenuated in the process of passing through the conductive nonwoven fabric of the present invention, and reflected in the reflective layer. The reflected radio wave is further attenuated by interference with the incident radio wave. As a result, it is considered that the reflection of the radio wave to the incident surface is inhibited, and that the radio wave thus does not transmit to the opposite side of the incident surface.

The reflective layer can be any layer that functions as a reflective layer for radio waves in a radio wave absorber. Examples of the reflective layer include, but are not limited to, metal films, metal foils, conductive materials, and the like.

The metal film can be any layer that includes metal as a material. The metal film may contain components other than metal, to the extent that the effect of the present invention is not significantly impaired. In this case, the total content of metal in the metal film is, for example, 30 mass % or more, preferably 50 mass % or more, more preferably 75 mass % or more, still more preferably 80 mass % or more, yet more preferably 90 mass % or more, particularly preferably 95 mass % or more, and very preferably 99 mass % or more, and typically less than 100 mass %.

The metal can be any metal. Examples of metals include aluminum, copper, iron, silver, gold, chromium, nickel, molybdenum, gallium, zinc, tin, niobium, and indium. Metal compounds, such as ITO, are also usable as a material of a metal film. These metals can be used singly, or in a combination of two or more.

The thickness of the reflective layer is not particularly limited. The thickness of the reflective layer is, for example, 1 μm or more and 500 μm or less, preferably 2 μm or more and 200 μm or less, and more preferably 5 μm or more and 100 μm or less.

The layer structure of the reflective layer is not particularly limited. The reflective layer may be composed of a single reflective layer, or a combination of two or more reflective layers.

When the radio wave absorber of the present invention has a reflective layer, the radio wave absorber of the present invention optionally has a dielectric layer in one embodiment. The dielectric layer is placed between the reflective layer and the conductive nonwoven fabric of the present invention.

The dielectric layer can be any dielectric layer that can function as a dielectric for a target wavelength in a radio wave absorber. Examples of dielectric layers include, but are not limited to, resin sheets and adhesives.

The resin sheet can be any resin in sheet form that contains resin as a material. The resin sheet may contain components other than resin, to the extent that the effect of the present invention is not significantly impaired. In this case, the total content of resin in the resin sheet is, for example, 50 mass % or more, preferably 70 mass % or more, more preferably 90 mass % or more, and still more preferably 95 mass % or more; and typically less than 100 mass %.

The resin can be any resin. The resin for use as a resin component is, for example, preferably a synthetic resin, such as ethylene vinyl acetate copolymers (EVA), vinyl chloride, urethane, acrylic, acrylic urethane, polyolefin, polyethylene, polypropylene, silicone, polyethylene terephthalate, polyester, polystyrene, polyimide, polycarbonate, polyamide, polysulfone, polyethersulfone, and epoxy; and a synthetic rubber material, such as polyisoprene rubber, polystyrene-butadiene rubber, polybutadiene rubber, chloroprene rubber, acrylonitrile-butadiene rubber, butyl rubber, acrylic rubber, ethylene-propylene rubber, and silicone rubber. These resins can be used singly, or in a combination of two or more.

The dielectric layer may be a foam or an adhesive.

The dielectric layer may have adhesiveness. Thus, when a dielectric with no adhesiveness is stacked on another layer via an adhesive layer, the combination of the dielectric and the adhesive layer forms a dielectric layer. From the standpoint of the ease of stacking a dielectric layer on an adjacent layer, the dielectric layer preferably contains an adhesive layer.

The layer structure of the dielectric layer is not particularly limited. The dielectric layer may be composed of a single dielectric layer, or a combination of two or more dielectric layers. Examples include a dielectric layer with a three-layered structure that includes a non-adhesive dielectric and an adhesive layer disposed on each surface of the non-adhesive dielectric, and a dielectric layer with a monolayer structure that includes an adhesive dielectric.

In the radio wave absorber of the present invention (in particular, in the case of having the reflective layer), the thickness d of the conductive nonwoven fabric of the present invention preferably satisfies formula (1): λ/16≤d (preferably λ/16≤d≤λ/4, more preferably λ/8≤d≤λ/4), wherein λ indicates the wavelength of the target radio wave. The thickness d in the above range will further improve radio wave absorption properties.

When the radio wave absorber of the present invention comprises a dielectric layer in addition to the reflective layer, the total d′ of the thickness of the conductive nonwoven fabric of the present invention and the thickness of the dielectric layer satisfies formula (1′): λ/16≤d′ (preferably λ/16≤d≤λ/4, and more preferably λ/8≤d′≤λ/4), wherein λ indicates the wavelength of the target radio wave.

λ is the wavelength of the radio wave targeted by the radio wave absorber of the present invention, and a suitable value is selected depending on the application. λ is the value obtained by dividing the light speed by the frequency. For example, it. is 0.2 cm or more and 1.5 cm or less, and preferably 0.3 cm or more and 1.2 cm or less.

### EXAMPLES

The present invention is described in detail with reference to the Examples below. However, the present invention is not limited to these Examples.

### (1) Production of Conductive Nonwoven Fabric Example 1

A spunlace nonwoven fabric (material: PET) with a thickness of 500 μm and a basis weight of 90 g/m² was used as a nonwoven fabric 1. The nonwoven fabric was set in a vacuum apparatus, and vacuum exhaustion was performed until the pressure became 5.0×10⁻⁴ Pa or less. Subsequently, an argon gas was introduced to set the gas pressure to 0.5 Pa. By the DC magnetron sputtering method, a barrier layer I composed of silicon, a metal layer composed of Hastelloy, and a barrier layer 2 composed of silicon were stacked on one surface of the nonwoven fabric in this order, thus obtaining a conductive nonwoven fabric.

### Example 2 to 10 and Comparative Examples 1 to 8

The conductive nonwoven fabric was obtained in the same manner as in Example 1, except that the type of the nonwoven fabric, the thickness of the nonwoven fabric, the basis weight of the nonwoven fabric, the amount of metal adhesion, and the structure of layers formed by sputtering were changed to those shown in the tables.

### Example 11

A conductive nonwoven fabric was obtained in the same manner as in Example 1, except that a nonwoven fabric 10 was used, the nonwoven fabric was placed in a vacuum apparatus to perform vacuum exhaustion until the pressure became 5.0×10⁻⁴ Pa or less; and, subsequently, sputtering was performed by introducing an argon gas to set the gas pressure to 0.25 Pa.

### Example 12

A conductive nonwoven fabric was obtained in the same manner as in Example 1, except that a nonwoven fabric 11 was used, the nonwoven fabric was placed in a vacuum apparatus to perform vacuum exhaustion until the pressure became 5.0×10⁻⁴ Pa or less; and, subsequently, sputtering was performed by introducing an argon gas to set the gas pressure to 0.25 Pa.

### Example 13

A conductive nonwoven fabric was obtained in the same manner as in Example 2, except that a nonwoven fabric was placed in a vacuum apparatus to perform vacuum exhaustion until the pressure became 5.0×10⁻⁴ Pa or less; and, subsequently, sputtering was performed by introducing an argon gas to set the gas pressure to 0.25 Pa.

The following nonwoven fabrics were used.

Nonwoven fabric 1: spunlace, material: PET, basis weight: 90 g/m², thickness: 500 μm
Nonwoven fabric 2: spunbond, material PET, basis weight: 50 g/m², thickness: 240 μm
Nonwoven fabric 3: melt-blown, material LCP, basis weight: 6 g/m², thickness: 18 μm
Nonwoven fabric 4: melt-blown, material PET, basis weight: 120 g/m², thickness: 178 μm
Nonwoven fabric 5: melt-blown, material PBT, basis weight: 20 g/m2., thickness: 178 μm
Nonwoven fabric 6: melt-blown, material PBT, basis weight: 86 g/m², thickness: 75 μm
Nonwoven fabric 7: spunlace, material PBT, basis weight: 25 g/m², thickness: 2300 μm
Nonwoven fabric 8: needle punch, material acrylic, basis weight: 35 g/m², thickness: 250 μm
Nonwoven fabric 9: needle punch, material PET, basis weight: 40 g/m², thickness: 300 μm
Nonwoven fabric 10: melt-blown, material LCP, basis weight: 70 g/m², thickness: 154 μm
Nonwoven fabric 11: needle punch, material PET, basis weight: 80 g/m², thickness: 2000 μm

### Comparative Example 9

Pulshut (product name: Pulshut, produced by Asahi Kasei Corporation) was used without any treatment. Pulshut had a basis weight of 45 g/m² and a thickness of 86 μm, and the surface of the conductive surface was insulated and protected by a resin sheet.

### (2) Production of Conductive Film

### Comparative Example 10

A PET film (thickness: 50 μm, basis weight: 70 g/m²) was placed in a vacuum apparatus to perform vacuum exhaustion until the pressure became 5.0×10⁻⁴ Pa or less. Subsequently, an argon gas was introduced, and by a DC magnetron sputtering method, a metal layer composed of Hastelloy was stacked on one surface of the film, thus obtaining a conductive film.

### (3) Evaluation Method

Various properties of the obtained conductive nonwoven fabrics and conductive film (hereinbelow collectively referred to as the “conductive substrate”) were evaluated.

### (3-1) Density Measurement

The density was calculated from the following formula (1), using the thickness of a sample obtained by measurement according to the method specified in JIS L 1913:2010 as a thickness, and the mass per unit area as a basis weight.

Density (g/m³)=basis weight (g/m²)/thickness(m) formula (1)

If a specimen of the required size could not be taken from the sample, the value obtained by applying a load of 0.5 kPa to the sample was used as a thickness.

### (3-2) Measurement of Sheet Resistance

The sheet resistance was measured by four-terminal sensing with a surface resistance tester (Loresta-EP, trade name, produced by Mitsubishi Chemical Analytech Co., Ltd.). Measurement was conducted using an ESP probe (MCP-TP08P, trade name, produced by Mitsubishi Chemical Analytech Co., Ltd.). The sample (Comparative Example 9) in which the conductive surface was insulated and protected by a resin sheet or the like was measured using an eddy current method with a non-contact resistance measurement instrument (EC-80P, trade name, produced by Napson Corporation).

### (3-3) Measurement of Element Adhesion Amount

The element adhesion amount was determined by X-ray fluorescence analysis. Specifically, the analysis was conducted using a scanning X-ray fluorescence analyzer (a ZSX Primus III+ scanning X-ray fluorescence spectrometer, produced by Rigaku Corporation) with an acceleration voltage of 50 kV, an acceleration current of 50 mA, and an integration time of 60 seconds. The X-ray intensity of the Ka ray of a component that is to be measured was measured, and the intensity at the background position was also measured in addition to the peak position; accordingly, the precise intensity could be calculated. From the calibration curve prepared in advance, the measured intensity value was converted to an adhesion amount. The same sample was analyzed five times, and the average was determined as the average adhesion amount.

### (3-4) Evaluation of Radio Wave Absorption Properties (Transmission) (Measurement of Loss Rate and S11)

A radio wave absorption measurement device was configured by using an N5227A PNA microwave network analyzer (produced by Keysight Technologies), an N5261A millimeter wave controller for PNA-X series 2-port (produced by Keysight Technologies), and an FSS-07 horn antenna (produced by HVS). Using this radio wave absorption measurement device, the return loss (S11) and transmission loss (S21) of the S-parameter were measured at each frequency by the S-parameter method, and the loss rate was calculated from the following formula (2).

Loss rate: (Ploss/Pin)=1−(S11² S21²)/1 formula (2).

### Evaluation of Radio Wave Absorption (Loss Rate)

The radio wave absorption was evaluated based on the loss rate at each frequency, according to the following criteria.

A: Loss rate: 0.45 or more
B: Loss rate: more than 0.40 and less than 0.45
C: Loss rate: 0.40 or less

### Evaluation of Radio Wave Reflectivity (S11)

The radio wave reflectivity was evaluated based on S11 at each frequency, according to the following criteria.

A: S11 was less than 0.16.
B: S11 was 0.16 or more and 0.25 or less
D: S11 exceeded 0.25.

### (3-5) Evaluation of Durability

The conductive substrate was subjected to a high-temperature, high-humidity test in which it was allowed to stand at a temperature of 85° C. and a humidity of 85% for 200 hours, and then the sheet resistance was measured. From the obtained resistant value, the rate of change in sheet resistance before and after the test resistance after the test—resistance before the test/resistance before the test) was obtained, and the durability was evaluated according to the following criteria.

A: 15% or less
B: more than 15% and 30% or less.
C: more than 30%.

### (3-6) Evaluation of Radio Wave Absorption Properties (Reflection) (Measurement of Loss Rate)

A reflective layer consisting of 30-μm-thick copper was adhered to the lower side of each of the conductive nonwoven fabrics of Examples 1 and 12 via 160-μm-thick adhesive tape (trade name: #575F produced by Sekisui Chemical Co., Ltd.) to prepare radio wave absorbers.

A radio wave absorption measurement device was configured by using an N5227A PNA microwave network analyzer (produced by Keysight Technologies), an N5261A millimeter wave controller for PNA-X series 2-port (produced by Keysight Technologies), and an FSS-07 horn antenna (produced by HVS). Using this radio wave absorption measurement device, the amounts of radio wave absorption of the obtained radio wave absorbers in the Ka band (26.5 to 45 GHz) and the W band (75 to 110 GHz) were measured based on JIS R1679. Each of the radio wave absorbers was set so that the radio wave incident direction was the metal layer side.

### Evaluation of Radio Wave Absorption (Loss Rate)

Regarding radio wave absorption, the loss rate was calculated based on the absorption amount (dB) at each frequency, and evaluated according to the following criteria.

A: Loss rate: 0.75 or more
B: Loss rate: less than 0.75 and 0.50 or more.
C: Loss rate: less than 0.50 and 0.25 or more
D: Loss rate: less than 0.25

### (3-7) Measurement of Gradient in Metal Adhesion Amount

For the conductive nonwoven fabrics of Examples 2, 11, 12, and 13, the gradient in the amount of metal adhesion (the slope of the graph of the high brightness area percentage and the thickness), and the metal adhesion range were measured in the following manner.

The slope of change in high brightness area percentage was calculated by analyzing a cross-sectional image obtained with an X-ray CT apparatus. A conductive nonwoven fabric was cut into a size of about 3 mm×3 mm×3 mm to prepare a measurement sample, and a three-dimensional image was obtained using an X-ray microscope (a nano3DX, produced by Rigaku Corporation).

### Example 11: Photograph Conditions

Number of projection images: 1200

### Binning: 2

Exposure time: 40 seconds per image
Spatial resolution: 0.54 μm/pixel

### Example 12: Photograph Conditions

Number of projection images: 1200

### Binning: 2

Exposure time: 15 seconds per image
Spatial resolution: 2.16 μm/pixel.

### Examples 2 and 13: Photograph Conditions

Number of projection images: 1200

### Binning: 2

Exposure time: 40 seconds per image
Spatial resolution: 0.54 μm/pixel

The obtained three dimensional images were analyzed with Avizo 9.7 image analysis software (produced by Thermo Fisher Scientific) and Image J Fiji image processing software (Dec. 30, 2017 version, open-source software) in the following manner.

Avizo 9.7 was used for the following Items (1) to (4), and Image J Fiji was used for the following Item (5).

(1) Images measured with an X-ray CT were taken as images having a 256-level (8-bit) brightness value, and reconstructed to obtain a three-dimensional image.
(2) The thickness direction was defined as the z-axis, slice images in the x-y plane were formed, and the images were cut so that each of the bottom surfaces of the x-y plane was quadrangle.
(3) Binarization was performed by the auto threshold function (moment) to select a conductive nonwoven fabric portion. Subsequently, noise was removed by opening to separate portions where the conductive nonwoven fabric was present and portions where only air was present.
(4) By masking, in each of the obtained three-dimensional images, only the portions where the conductive nonwoven fabric was present were extracted, and an adjustment was performed so that the brightness values of the other portions are 0.
(5) Using image processing software, the count number of pixels having a brightness value of 1 or more (the total brightness area) and the count number of pixels having a brightness value equal to or greater than the threshold value (high brightness area) were obtained for each slice image. The average of the maximum values of the brightness value at respective thickness positions in the range between the lower surface of the conductive nonwoven fabric and 5% of the thickness of the conductive nonwoven fabric was defined as the threshold value.
(6) By plotting the thickness position (mm) and the high brightness area percentage (%) on the X-axis (mm) and the Y-axis, respectively, a graph of the high brightness area percentage and the thickness was formed. The high brightness area percentage means the percentage of the high brightness area to the total brightness area.
(7) From the graph prepared, the slope of the graph obtained by plotting the high brightness area percentage and the thickness, the thickness position at the point indicating 50% of the maximum value of the high brightness area percentage, and the range of metal adhesion from the surface of the conductive nonwoven fabric were obtained.

### (4) Evaluation Results

The configurations and evaluation results of conductive substrates are shown in Tables 1 to 3. In the tables, Hastelloy is an alloy of the following composition: molybdenum: 16.4 wt %, nickel: 55.2 wt %, chromium: 18.9 wt %, iron: 5.5 wt %, tungsten: 3.5 wt %, and silica: 0.5 wt %. Stainless steel is an alloy of the following composition: iron: 54 wt %, chromium: 26 wt %, nickel: 19 wt %, manganese: 1 wt %. Monel is an alloy of the following composition: nickel: 65 wt %, copper: 33 wt %, and iron: 2 wt %.

TABLE 1

| | | | Example 1 | Example 2 | Example 3 | Example 4 | Example 5 | Example 6 | Example 7 |
|---|---|---|---|---|---|---|---|---|---|
| Metal layer | Adhesion | Element | 60 | 34 | 11 | 112 | 31 | 112 | 39 |
| | amount | adhesion | | | | | | | |
| | (μg/cm²) | amount | | | | | | | |
| | | Metal layer | 52 | 26 | 8 | 104 | 24 | 104 | 31 |
| | | Barrier layer | 4.0 | 4.0 | 1.5 | 4.0 | 3.5 | 4.0 | 4.0 |
| | | Barrier layer | 4.0 | 4.0 | 1.5 | 4.0 | 3.5 | 4.0 | 4.0 |
| | Layer structure | | Si/Hastelloy/Si | | | | | | |
| Substrate | Kind | | Nonwoven | Nonwoven | Nonwoven | Nonwoven | Nonwoven | Nonwoven | Nonwoven |
| | | | fabric 1 | fabric 2 | fabric 3 | fabric 4 | fabric 5 | fabric 1 | fabric 1 |
| | Thickness (μm) | | 500 | 240 | 18 | 178 | 178 | 500 | 500 |
| | Basis weight (g/m²) | | 90 | 50 | 6 | 120 | 20 | 90 | 90 |
| Conductive | Density (g/m³) | | 1.80 × 10⁵ | 2.08 × 10⁵ | 3.33 × 10⁵ | 6.74 × 10⁵ | 1.12 × 10⁵ | 1.80 × 10⁵ | 1.80 × 10⁵ |
| nonwoven | Sheet resistance (Ω/□) | | 380 | 350 | 390 | 380 | 380 | 210 | 580 |
| fabric | | | | | | | | | |
| Absorption | @28 GHz | Loss rate | 0.50 | 0.42 | 0.47 | 0.41 | 0.43 | 0.46 | 0.42 |
| properties | | S11 | 0.13 | 0.06 | 0.07 | 0.05 | 0.09 | 0.20 | 0.10 |
| (transmission) | @39 GHz | Loss rate | 0.50 | 0.43 | 0.43 | 0.42 | 0.48 | 0.46 | 0.43 |
| | | S11 | 0.14 | 0.09 | 0.09 | 0.05 | 0.10 | 0.21 | 0.14 |
| | @79 GHz | Loss rate | 0.51 | 0.46 | 0.49 | 0.43 | 0.50 | 0.47 | 0.45 |
| | | S11 | 0.22 | 0.11 | 0.08 | 0.06 | 0.11 | 0.24 | 0.18 |
| Absorption | @28 GHz | Loss rate | A | B | A | B | B | A | B |
| properties | | S11 | A | A | A | A | A | B | A |
| (transmission) | @39 GHz | Loss rate | A | B | B | B | A | A | B |
| | | S11 | A | A | A | A | A | B | A |
| | @79 GHz | Loss rate | A | A | A | B | A | A | A |
| | | S11 | B | A | A | A | A | B | B |

| | | | | | | | |
|---|---|---|---|---|---|---|---|
| Durability | B | B | B | B | B | B | B |

| | | | Example 8 | Example 9 | Example 10 | Example 11 | Example 12 |
|---|---|---|---|---|---|---|---|
| Metal layer | Adhesion | Element | 52 | 82 | 32 | 47 | 28 |
| | amount | adhesion | | | | | |
| | (μg/cm²) | amount | | | | | |
| | | Metal layer | 52 | 74 | 24 | 39 | 20 |
| | | Barrier layer | — | 4.0 | 4.0 | 4.0 | 4.0 |
| | | Barrier layer | — | 4.0 | 4.0 | 4.0 | 4.0 |
| | Layer structure | | Hastelloy | Si/Hastelloy/Si | | | |
| Substrate | Kind | | Nonwoven | Nonwoven | Nonwoven | Nonwoven | Nonwoven |
| | | | fabric 1 | fabric 8 | fabric 9 | fabric 10 | fabric 11 |
| | Thickness (μm) | | 500 | 250 | 300 | 154 | 2000 |
| | Basis weight (g/m²) | | 90 | 35 | 40 | 70 | 80 |
| Conductive | Density (g/m³) | | 1.80 × 10⁵ | 1.40 × 10⁵ | 1.33 × 10⁵ | 4.55 × 10⁵ | 4.00 × 10⁴ |
| nonwoven | Sheet resistance (Ω/□) | | 400 | 300 | 380 | 380 | 380 |
| fabric | | | | | | | |
| Absorption | @28 GHz | Loss rate | 0.46 | 0.46 | 0.43 | 0.41 | 0.49 |
| properties | | S11 | 0.09 | 0.18 | 0.06 | 0.04 | 0.06 |
| (transmission) | @39 GHz | Loss rate | 0.48 | 0.49 | 0.45 | 0.42 | 0.57 |
| | | S11 | 0.11 | 0.19 | 0.06 | 0.05 | 0.04 |
| | @79 GHz | Loss rate | 0.50 | 0.54 | 0.48 | 0.44 | 0.67 |
| | | S11 | 0.14 | 0.21 | 0.05 | 0.08 | 0.02 |
| Absorption | @28 GHz | Loss rate | A | A | B | B | A |
| properties | | S11 | A | B | A | A | A |
| (transmission) | @39 GHz | Loss rate | A | A | A | B | A |
| | | S11 | A | B | A | A | A |
| | @79 GHz | Loss rate | A | A | A | B | A |
| | | S11 | A | B | A | A | A |

| | | | | | |
|---|---|---|---|---|---|
| Durability | C | B | B | B | B |

TABLE 2

| | | | Comparative | Comparative | Comparative | Comparative | Comparative | Comparative |
|---|---|---|---|---|---|---|---|---|
| | | | Example 1 | Example 2 | Example 3 | Example 4 | Example 5 | Example 6 |
| Metal layer | Adhesion | Element | 119 | 28 | 164 | 13 | 54 | 301 |
| | amount | adhesion | | | | | | |
| | (μg/cm²) | amount | | | | | | |
| | | Metal layer | 111 | 20 | 156 | 9 | 54 | 255 |
| | | Barrier layer | 4.0 | 4.0 | 4.0 | 2.0 | — | 23.0 |
| | | Barrier layer | 4.0 | 4.0 | 4.0 | 2.0 | — | 23.0 |
| | Layer structure | | Si/Hastelloy/Si | | | | Stainless | Monel/Cu/Monel |
| | | | | | | | steel | |
| Substrate | Kind | | Nonwoven | Nonwoven | Nonwoven | Nonwoven | Nonwoven | Nonwoven |
| | | | fabric 1 | fabric 1 | fabric 1 | fabric 1 | fabric 1 | fabric 1 |
| | Thickness (μm) | | 500 | 500 | 500 | 500 | 500 | 500 |
| | Basis weight (g/m²) | | 90 | 90 | 90 | 90 | 90 | 90 |
| Conductive | Density (g/m³) | | 1.80 × 10⁵ | 1.80 × 10⁵ | 1.80 × 10⁵ | 1.80 × 10⁵ | 1.80 × 10⁵ | 1.80 × 10⁵ |
| substrate | Sheet resistance (Ω/□) | | 160 | 750 | 80 | 1000 | 2300 | 1.6 |
| Absorption | @28 GHz | Loss rate | 0.47 | 0.39 | 0.42 | 0.35 | 0.32 | 0.12 |
| properties | | S11 | 0.27 | 0.06 | 0.43 | 0.04 | 0.03 | 0.73 |
| (transmission) | @39 GHz | Loss rate | 0.45 | 0.41 | 0.40 | 0.37 | 0.34 | 0.12 |
| | | S11 | 0.29 | 0.07 | 0.46 | 0.04 | 0.02 | 0.77 |
| | @79 GHz | Loss rate | 0.45 | 0.42 | 0.43 | 0.41 | 0.39 | 0.13 |
| | | S11 | 0.31 | 0.09 | 0.58 | 0.07 | 0.04 | 0.83 |
| Absorption | @28 GHz | Loss rate | A | D | B | D | D | D |
| properties | | S11 | D | A | D | A | A | D |
| (transmission) | @39 GHz | Loss rate | A | B | D | D | D | D |
| | | S11 | D | A | D | A | A | D |
| | @79 GHz | Loss rate | A | B | B | B | D | D |
| | | S11 | D | A | D | A | A | D |

| | | | | | | |
|---|---|---|---|---|---|---|
| Durability | B | B | B | B | C | D |

| | | | Comparative | Comparative | Comparative | Comparative |
|---|---|---|---|---|---|---|
| | | | Example 7 | Example 8 | Example 9 | Example 10 |
| Metal layer | Adhesion | Element | 17 | 373 | 12 | 9 |
| | amount | adhesion | | | | |
| | (μg/cm²) | amount | | | | |
| | | Metal layer | 9 | 367 | 12 | 6 |
| | | Barrier layer | 4.0 | 3.0 | — | 1.5 |
| | | Barrier layer | 4.0 | 3.0 | — | 1.5 |
| | Layer structure | | Si/Hastelloy/Si | | Al | Si/Hastelloy/Si |
| Substrate | Kind | | Nonwoven | Nonwoven | — | — |
| | | | fabric 6 | fabric 7 | | |
| | Thickness (μm) | | 75 | 2300 | 50 | 50 |
| | Basis weight (g/m²) | | 86 | 25 | 45 | 70 |
| Conductive | Density (g/m³) | | 1.15 × 10⁶ | 1.09 × 10⁴ | 9.00 × 10⁵ | 1.40 × 10⁶ |
| substrate | Sheet resistance (Ω/□) | | 380 | 380 | 20 | 380 |
| Absorption | @28 GHz | Loss rate | 0.31 | 0.33 | 0.38 | 0.40 |
| properties | | S11 | 0.05 | 0.03 | 0.47 | 0.04 |
| (transmission) | @39 GHz | Loss rate | 0.33 | 0.36 | 0.35 | 0.40 |
| | | S11 | 0.04 | 0.02 | 0.49 | 0.04 |
| | @79 GHz | Loss rate | 0.36 | 0.39 | 0.41 | 0.40 |
| | | S11 | 0.04 | 0.01 | 0.40 | 0.04 |
| Absorption | @28 GHz | Loss rate | D | D | D | D |
| properties | | S11 | A | A | D | A |
| (transmission) | @39 GHz | Loss rate | D | D | D | D |
| | | S11 | A | A | D | A |
| | @79 GHz | Loss rate | D | D | B | D |
| | | S11 | A | A | D | A |

| | | | | |
|---|---|---|---|---|
| Durability | B | B | D | B |

TABLE 3

| | | | Example 1 | Example 12 |
|---|---|---|---|---|
| Metal layer | Adhesion | Element | 60 | 28 |
| | amount | adhesion | | |
| | (μg/cm²) | amount | | |
| | | Metal layer | 52 | 20 |
| | | Barrier layer | 4.0 | 4.0 |
| | | Barrier layer | 4.0 | 4.0 |
| | Layer structure | | Si/Hastelloy/Si | |
| Substrate | Kind | | Nonwoven | Nonwoven |
| | | | fabric 1 | fabric 11 |
| | Thickness (μm) | | 500 | 2000 |
| | Basis weight (g/m²) | | 90 | 80 |
| Conductive | Density (g/m³) | | 1.80 × 10⁵ | 4.00 × 10⁴ |
| nonwoven fabric | Sheet resistance | | 380 | 380 |
| | (Ω/□) | | | |
| Absorption | @28 GHz | Loss rate | 0.71 | 0.92 |
| properties | @39 GHz | Loss rate | 0.78 | 0.75 |
| (reflection) | @79 GHz | Loss rate | 0.87 | 0.86 |
| Absorption | @28 GHz | Loss rate | B | A |
| properties | @39 GHz | Loss rate | A | A |
| (reflection) | @79 GHz | Loss rate | A | A |

TABLE 4

| | | | Example 2 | Example 11 | Example 12 | Example 13 |
|---|---|---|---|---|---|---|
| Metal layer | Adhesion | Element | 34 | 47 | 28 | 34 |
| | amount | adhesion | | | | |
| | (μg/cm²) | amount | | | | |
| | | Metal layer | 26 | 39 | 20 | 26 |
| | | Barrier layer | 4.0 | 4.0 | 4.0 | 4.0 |
| | | Barrier layer | 4.0 | 4.0 | 4.0 | 4.0 |
| | Layer structure | | Si/Hastelloy/Si | | | |
| Substrate | Kind | | Nonwoven | Nonwoven | Nonwoven | Nonwoven |
| | | | fabric 2 | fabric 10 | fabric 11 | fabric 2 |
| | Thickness (μm) | | 240 | 154 | 2000 | 240 |
| | Basis weight (g/m²) | | 50 | 70 | 80 | 50 |
| Conductive | Density (g/m³) | | 2.08 × 10⁵ | 4.55 × 10⁵ | 4.00 × 10⁴ | 2.08 × 10⁵ |
| nonwoven fabric | Sheet resistance (Ω/□) | | 350 | 380 | 380 | 350 |
| | Slope of change in metal | | −1892 | −2375 | −18 | −1523 |
| | distribution | | | | | |
| | Thickness position (μm) | | 27 | 8.1 | 540 | 33 |
| | where the value is 50% of the | | | | | |
| | maximum value of the high | | | | | |
| | brightness area percentage. | | | | | |
| | Metal adhesion range (μm) | | 64 | 20 | 1100 | 81 |
| Absorption | @28 GHz | Loss rate | 0.42 | 0.41 | 0.49 | 0.43 |
| properties | | S11 | 0.06 | 0.04 | 0.06 | 0.06 |
| (transmission) | @39 GHz | Loss rate | 0.43 | 0.42 | 0.57 | 0.45 |
| | | S11 | 0.09 | 0.05 | 0.04 | 0.08 |
| | @79 GHz | Loss rate | 0.46 | 0.44 | 0.67 | 0.50 |
| | | S11 | 0.11 | 0.08 | 0.02 | 0.08 |
| Absorption | @28 GHz | Loss rate | B | B | A | B |
| properties | | S11 | A | A | A | A |
| (transmission) | @39 GHz | Loss rate | B | B | A | A |
| | | S11 | A | A | A | A |
| | @79 GHz | Loss rate | A | B | A | A |
| | | S11 | A | A | A | A |

### DESCRIPTION OF THE REFERENCE NUMERALS

1. metal layer
2. barrier layer
3. nonwoven fabric
4. metal chassis
5. conductive nonwoven fabric (disposed at the inner wall of the metal chassis)
6. conductive nonwoven fabric (disposed at the opening)
7. IC chip
8. conductive nonwoven fabric
9. resin chassis
10. conductive nonwoven fabric (disposed inside the chassis)
11. dielectric layer
12. adhesive layer
13. reflective layer

1. A conductive nonwoven fabric comprising a metal layer on at least one surface thereof, the conductive nonwoven fabric having a sheet resistance of 200 to 600 Ω/□ and a density of 2.0×10⁴ to 8.0×10⁵ g/m³.

2. The conductive nonwoven fabric according to claim 1, having an adhesion amount of a metal element and/or a metalloid element of 5 to 150 μg /cm².

3. The conductive nonwoven fabric according to claim 1, comprising a barrier layer containing at least one element selected from the group consisting of nickel, silicon, titanium, and aluminum on at least one surface of the metal layer.

4. The conductive nonwoven fabric according to claim 1, wherein the metal layer contains at least one element selected from the group consisting of nickel, molybdenum, chromium, titanium, and aluminum.

5. The conductive nonwoven fabric according to claim 1, wherein the slope of change in high brightness area percentage measured with an X-ray CT apparatus is −3000 or more and −10 or less.

6. A radio wave absorber comprising the conductive nonwoven fabric according to claim 1.

7. The radio wave absorber according to claim 6, wherein the conductive nonwoven fabric further comprises an adhesive layer.

8. The radio wave absorber according to claim 6, wherein the thickness d of the conductive nonwoven fabric satisfies formula (1): λ/16≤d, wherein λ is the wavelength of a target radio wave.

9. The radio wave absorber according to claim 8, comprising the conductive nonwoven fabric and a reflective layer, wherein the reflective layer is placed on a surface opposite to the surface of the conductive nonwoven fabric having a sheet resistance of 200 to 600 Ω/□.

10. A chassis comprising the radio wave absorber according to claim 6.

11. The chassis according to claim 10, wherein the conductive nonwoven fabric is placed on an inner surface of the chassis.

12. The chassis according to claim 10, wherein the conductive nonwoven fabric is placed in an opening of the chassis.

13. An electronic device comprising the radio wave absorber according to claim 6 or a chassis comprising the radio wave absorber according to claim 6.
